(19) United States
(12) Patent Application Publication
(10) Pub. No.: US 2015/0070999 A1
(43) Pub. Date: Mar. 12, 2015

(54) NONVOLATILE SEMICONDUCTOR MEMORY DEVICE

(71) Applicant: Kabushiki Kaisha Toshiba, Minato-ku (JP)

(72) Inventors: Shun Shibata, Yokkaichi-shi (JP); Masayuki Ichige, Yokkaichi-shi (JP); Jun Ogi, Yokohama-shi (JP)

(73) Assignee: Kabushiki Kaisha Toshiba, Minato-ku (JP)

(21) Appl. No.: 14/147,763

(22) Filed: Jan. 6, 2014

Related U.S. Application Data
(60) Provisional application No. 61/876,400, filed on Sep. 11, 2013.

(51) Int. Cl. G11C 16/10; G11C 16/26

(52) U.S. Cl. CPC G11C 16/10; G11C 16/26
USPC 365/185.17; 365/185.18; 365/185.22

(57) ABSTRACT

According to an embodiment, a nonvolatile semiconductor memory device includes a plurality of memory cells and a control circuit. The memory cell includes a semiconductor layer, a gate insulating layer, a floating gate, a lower control gate, and an upper control gate. The semiconductor layer extends in a certain direction. The lower control gate is formed on the floating gate via an insulating layer. The upper control gate is formed on the lower control gate via an insulating layer. In addition, the control circuit, when performing a write operation, applies a first pass voltage to the upper control gate in a selected memory cell, and applies a first write voltage which is larger than the first pass voltage to the upper control gate in an adjacent memory cell formed on an identical semiconductor layer to the selected memory cell and adjacent to the selected memory cell.

### CROSS-REFERENCE TO RELATED APPLICATIONS

This application is based upon and claims the benefit of U.S. Provisional Patent Application No. 61/876,400, filed on Sep. 11, 2013, the entire contents of which are incorporated herein by reference.

### FIELD

Embodiments described here relate to a nonvolatile semiconductor memory device.

### BACKGROUND

### Description of the Related Art

A memory cell configuring a nonvolatile semiconductor memory device such as a NAND type flash memory and a NOR type flash memory includes a control gate and a charge accumulation layer. The memory cell changes its threshold voltage according to a charge accumulated in the charge accumulation layer to store a magnitude of this threshold voltage as data. In recent years, a rise in density level of the memory cell has been proceeding in such a nonvolatile semiconductor memory device.

### BRIEF DESCRIPTION OF THE DRAWINGS

FIG. 1 is a block diagram showing a configuration of a nonvolatile semiconductor memory device according to a first embodiment.

FIG. 2 is a circuit diagram showing a configuration of part of a memory cell array in same nonvolatile semiconductor memory device.

FIG. 3 is a schematic cross-sectional view showing part of same memory cell array.

FIG. 4 is a schematic cross-sectional view for explaining a write operation of a nonvolatile semiconductor memory device according to a comparative example.

FIG. 5 is a schematic cross-sectional view for explaining a write operation of the nonvolatile semiconductor memory device according to the first embodiment.

FIG. 6 is a timing chart for explaining same write operation.

FIG. 7 is a schematic cross-sectional view for explaining a read operation of same nonvolatile semiconductor memory device.

FIG. 8 is a timing chart for explaining same read operation.

FIG. 9 is a timing chart for explaining an erase operation of same nonvolatile semiconductor memory device.

FIG. 10 is a schematic cross-sectional view showing part of a memory cell array in a nonvolatile semiconductor memory device according to a second embodiment.

FIG. 11 is a schematic plane view showing part of same memory cell array.

FIG. 12 is a schematic cross-sectional view for explaining a write operation of same nonvolatile semiconductor memory device.

FIG. 13 is a schematic cross-sectional view for explaining a read operation of same nonvolatile semiconductor memory device.

### DETAILED DESCRIPTION

A nonvolatile semiconductor memory device according to an embodiment includes a memory cell array and a control circuit. The memory cell array has a plurality of memory cells. The plurality of memory cells are arranged in a first direction to share a source and a drain with each other. The memory cell includes a semiconductor layer, a gate insulating layer, a floating gate, a first inter-gate insulating layer, a lower control gate, a second inter-gate insulating layer, and an upper control gate. The gate insulating layer is formed on the semiconductor layer. The floating gate is formed on the gate insulating layer. The first inter-gate insulating layer is formed on the floating gate. The lower control gate is formed on the first inter-gate insulating layer. The second inter-gate insulating layer is formed on the lower control gate. The upper control gate is formed on the second inter-gate insulating layer. In addition, the control circuit, when performing a write operation on a certain selected memory cell, applies a first pass voltage to the upper control gate in the selected memory cell, and applies a first write voltage which is larger than the first pass voltage to the upper control gate in an adjacent memory cell adjacent to the selected memory cell in the first direction.

A nonvolatile semiconductor memory device according to another embodiment includes a memory cell array and a control circuit. The memory cell array has a plurality of memory cells. The plurality of memory cells are arranged in a first direction to share a source and a drain with each other. The memory cell includes a semiconductor layer, agate insulating layer, a floating gate, a first inter-gate insulating layer, a lower control gate, a second inter-gate insulating layer, and an upper control gate. The gate insulating layer is formed on the semiconductor layer. The floating gate is formed on the gate insulating layer. The first inter-gate insulating layer is formed on the floating gate. The lower control gate is formed on the first inter-gate insulating layer. The second inter-gate insulating layer is formed on the lower control gate. The upper control gate is formed on the second inter-gate insulating layer. In addition, the control circuit, when performing a read operation on a certain selected memory cell, applies a first read voltage to the upper control gate in an adjacent memory cell adjacent to the selected memory cell in the first direction, and applies a second read voltage which is larger than the first read voltage to the lower control gate in the adjacent memory cell.

A nonvolatile semiconductor memory device according to yet another embodiment includes a memory cell array and a control circuit. The memory cell array has a plurality of memory cells. The plurality of memory cells are arranged in a first direction to share a source and a drain with each other. The memory cell includes a semiconductor layer, a gate insulating layer, a floating gate, a first inter-gate insulating layer, a lower control gate, a second inter-gate insulating layer, and an upper control gate. The gate insulating layer is formed on the semiconductor layer. The floating gate is formed on the gate insulating layer. The first inter-gate insulating layer is formed on the floating gate. The lower control gate is formed on the first inter-gate insulating layer. The second inter-gate insulating layer is formed on the lower control gate. The upper control gate is formed on the second inter-gate insulating layer. In addition, the upper control gate is formed in a planar shape extending in a plane substantially perpendicular to a stacking direction of the memory cell. Moreover, the control circuit applies a voltage to a memory cell array.

A semiconductor memory device according to embodiments of the present invention will be described below with reference to the drawings.

### First Embodiment

[Overall Configuration]

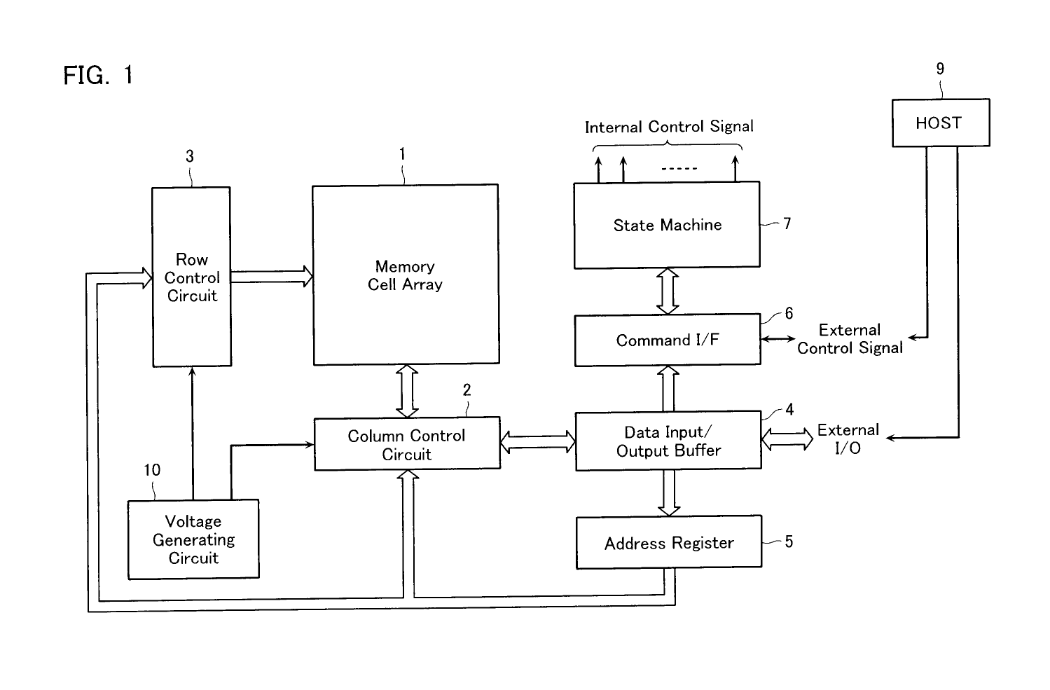

FIG. 1 is a block diagram of a nonvolatile semiconductor memory device according to a first embodiment of the present invention. This nonvolatile semiconductor memory device includes a memory cell array 1 having a plurality of memory cells MC arranged in a matrix therein, and comprising a bit line BL and a word line WL (including both of an upper word line UWL and a lower word line LWL which will be mentioned later, the same applying below) disposed orthogonally to each other and connected to these memory cells MC. Provided in a periphery of this memory cell array 1 are a column control circuit 2 and a row control circuit 3. The column control circuit 2 controls the bit line BL to perform data erase of the memory cell, data write to the memory cell, and data read from the memory cell. The row control circuit 3 selects the word line WL to apply a voltage for data erase of the memory cell, data write to the memory cell, and data read from the memory cell.

A data input/output buffer 4 is connected to an external host 9, via an I/O line, to receive write data, receive an erase command, output read data, and receive address data or command data. The data input/output buffer 4 sends write data received from the external host 9 to the column control circuit 2, and receives data read from the column control circuit 2 to output the data to external. An address supplied to the data input/output buffer 4 from external is sent to the column control circuit 2 and the row control circuit 3 via an address register 5.

Moreover, a command supplied to the data input/output buffer 4 from the host 9 is sent to a command interface 6. The command interface 6 receives an external control signal from the host 9 to determine whether data inputted to the data input/output buffer 4 is write data or a command or an address, and, if the data is a command, receives the data and transfers the data to a state machine 7 as a command signal.

The state machine 7 performs management of this nonvolatile memory overall, and receives a command from the host 9, via the command interface 6, to perform management of read, write, erase, input/output of data, and so on.

In addition, it is also possible for status information managed by the state machine 7 to be received by the external host 9, thereby enabling the external host 9 to judge an operation result. Moreover, this status information is utilized also in control of write and erase.

Furthermore, the state machine 7 controls a voltage generating circuit 10. This control enables the voltage generating circuit 10 to output a pulse of any voltage and any timing.

The pulse formed by the voltage generating circuit 10 can be transferred to any line selected by the column control circuit 2 and the row control circuit 3. These column control circuit 2, row control circuit 3, state machine 7, and voltage generating circuit 10, and so on, configure a control circuit in the present embodiment.

[Memory Cell Array]

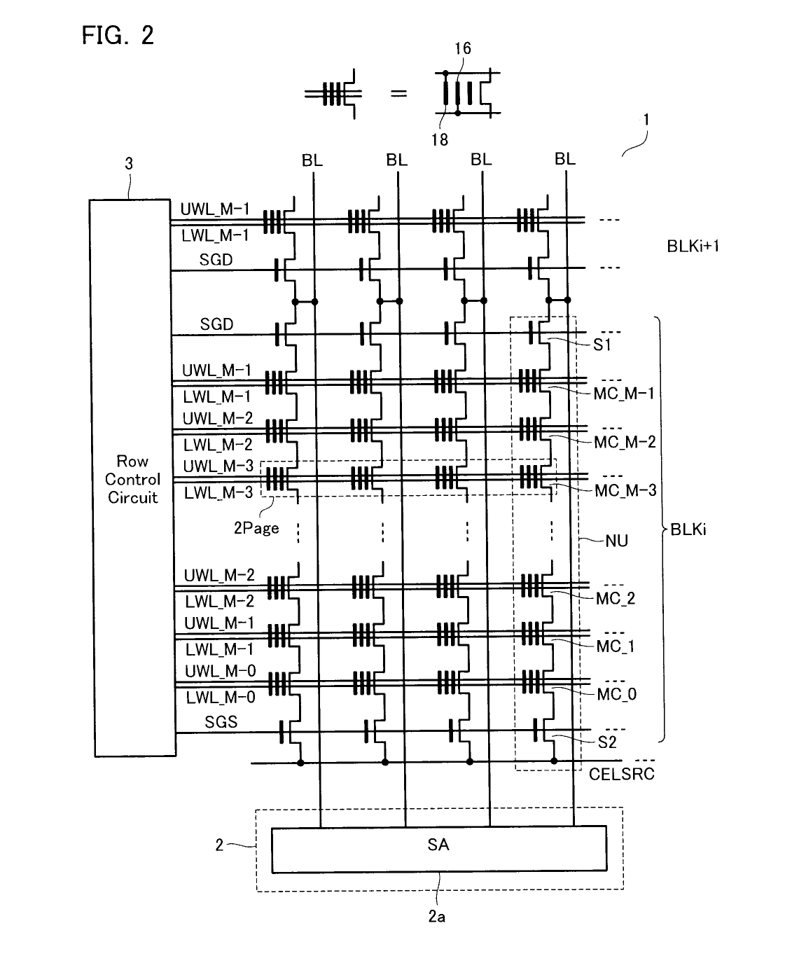

FIG. 2 is a circuit diagram showing a configuration in the case where the memory cell array 1 is of a NAND type. As shown in FIG. 2, the memory cell array 1 is configured having NAND cell units NU arranged therein, each of the NAND cell units NU being configured having select gate transistors S1 and S2 respectively connected to both ends of a NAND string, the NAND string having M electrically rewritable nonvolatile memory cells MC_{—}0 to MC_M−1 connected in series therein, sharing a source and a drain.

The NAND cell unit NU has one end (a select gate transistor S1 side) connected to the bit line BL and the other end (a select gate transistor S2 side) connected to a common source line CELSRC. Gate electrodes of the select gate transistors S1 and S2 are connected to select gate lines SGD and SGS. In addition, the memory cells MC_{—}0 to MC_M−1 according to the present embodiment each include two control gates, upper control gates 18 being respectively connected to upper word lines UWL_{—}0 to UWL_M−1, and lower control gates 16 being respectively connected to lower word lines LWL_{—}0 to LWL_M−1. The bit line BL is connected to a sense amplifier 2a of the column control circuit 2, and the upper word lines UWL_{—}0 to UWL_M−1, lower word lines LWL_{—}0 to LWL_M−1, and the select gate lines SGD and SGS are connected to the row control circuit 3.

One memory cell MC is capable of storing data of x bits (for example, 1 bit (2 levels), 2 bits (4 levels), 3 bits (8 levels), and so on), and data stored in the plurality of memory cells MC connected to one word line WL configures x pages of data.

One block BLK is formed by the plurality of NAND cell units NU sharing the word line WL. The one block BLK forms a single unit of a data erase operation. If the number of lower word lines LWL in one block BLK in one memory cell array 1 is assumed to be M, then the number of pages in one block BLK is M times x.

[Configuration of Memory Cell MC and Select Gate Transistors S1 and S2]

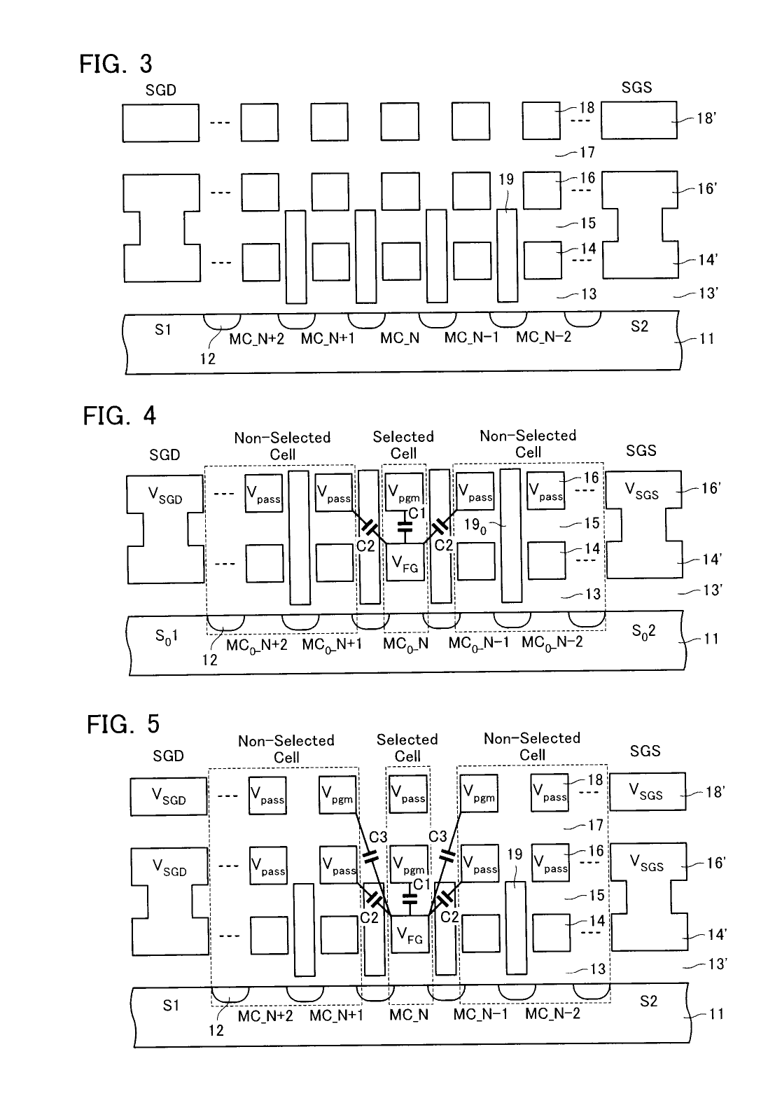

FIG. 3 shows schematically a cross-sectional structure of the memory cells MC_{—}0 to MC_M−1 and the select gate transistors S1 and S2. As shown in FIG. 3, an n type diffusion layer 12 is formed in a p type well 11, the p type well 11 being formed in a substrate and extending in a first direction. The n type diffusion layer 12 functions as a source and a drain of a MOSFET configuring the memory cell MC. Moreover, a floating gate 14 functioning as a charge accumulation layer is formed on the p type well 11 via a tunnel insulating layer 13, and the lower control gate 16 is formed on this floating gate 14 via a first inter-gate insulating layer 15. The lower control gate 16 extends in a second direction intersecting the first direction to configure the lower word line LWL. In addition, the upper control gate 18 is formed on the lower control gate 16 via a second inter-gate insulating layer 17. The upper control gate 18 extends in the second direction to configure the upper word line UWL. These p type well 11, tunnel insulating layers 13, floating gates 14, first inter-gate insulating layers 15, lower control gates 16, second inter-gate insulating layers 17, and upper control gates 18 configure the plurality of memory cells MC_{—}0 to MC_M−1 arranged in the first direction to share a source and a drain with each other. Note that in the present embodiment, the floating gate 14, the lower control gate 16, and the upper control gate 18 are formed in an identical process. Therefore, positions of the floating gate 14, the lower control gate 16, and the upper control gate 18 are matched in the first direction.

A gap 19 is formed at a position adjacent to each of the memory cells MC in a direction of extension of the above-described p type well 11. It is also possible to say that the gaps 19 are formed between each of the plurality of memory cells MC_{—}0 to MC_M−1. A lower end of the gap 19 is positioned at a height between a surface of the p type well 11 and a lower end of the floating gate 14. Moreover, an upper end of the gap 19 is positioned at a height up to around a lower end of the lower control gate 16. In the present embodiment, the upper end of the gap 19 is positioned at the lower end of the lower control gate 16. Note that the nonvolatile semiconductor memory device according to the present embodiment includes the gap 19, but it is also possible to adopt a structure in which the gap 19 is not provided.

The select gate transistors S1 and S2 are formed at both ends of the memory cells MC_{—}0 to MC_M−1. The select gate transistors S1 and S2 comprise the p type well 11, a select gate insulating layer 13′ formed on the p type well 11, and a gate electrode formed on the select gate insulating layer 13′. In the present embodiment, an electrode 14′ formed at a height corresponding to the floating gate 14 and an electrode 16′ formed at a height corresponding to the lower control gate 16 are connected to configure the gate electrode. Note that the gate electrodes extend in a direction intersecting the direction of extension of the p type well 11 to configure the select gate lines SGD and SGS. In addition, upper gate electrodes 18′ are formed on the select gate transistors S1 and S2 via the above-described second inter-gate insulating layer 17. Said upper gate electrodes 18′ may be used independently. Moreover, it is also possible to suppress the number of lead-out lines by omitting the upper gate electrodes 18′ or connecting the upper gate electrodes 18′ to the gate electrodes SGD and SGS to be electrically integrated therewith.

[Operation]

Next, operations of the nonvolatile semiconductor memory device according to the present embodiment will be described. First, prior to the description of the operations of the nonvolatile semiconductor memory device according to the present embodiment, an operation of a nonvolatile semiconductor memory device according to a comparative example will be described.

[Write Method in Nonvolatile Semiconductor Memory Device According to Comparative Example]

FIG. 4 is a schematic view for explaining a write method in the nonvolatile semiconductor memory device according to the comparative example. In the nonvolatile semiconductor memory device according to the comparative example, the second inter-gate insulating layer 17, the upper control gate 18 and the upper gate electrode 18′ are not formed. Moreover, in the comparative example, an upper end of a gap 19₀ is positioned above an upper end of a control gate 16 (corresponding to the lower control gate 16 in the first embodiment).

In the nonvolatile semiconductor memory device according to the comparative example, a voltage V_{SGD} is applied to the gate electrode of a select gate transistor S₀1, and the p type well 11 is connected to the bit line BL. Following this, a voltage of the control gates 16 is raised to a pass voltage Vₚₐₛₛ. As a result, a channel is formed on the p type well 11 and a selected memory cell MC₀_{_{—}}N is electrically connected to the bit line BL. Note that the pass voltage Vₚₐₛₛ is a voltage of a magnitude that sets the memory cell MC₀ to an ON state regardless of a state of the floating gate 14 and at which charge accumulation to the floating gate 14 does not occur.

Next, a voltage of the control gate 16 in the selected memory cell MC₀_{_{—}}N is further raised to a write voltage V_{pgm} (second write voltage). As a result, a potential difference occurs between a lower surface of the floating gate 14 and the p type well 11, and electrons supplied from the bit line BL via the channel formed in the p type well 11 are accumulated in the floating gate 14 by a tunnel current. Note that the write voltage V_{pgm} is a voltage of a magnitude at which a charge is accumulated in the floating gate 14 of the selected memory cell MC₀_{_{—}}N and is larger than the pass voltage Vₚₐₛₛ. Moreover, in the case where the memory cell MC₀ stores multiple data, the write voltage V_{pgm} is set to multiple types corresponding to the data to be stored in the memory cell MC₀.

Now, as miniaturization of the nonvolatile semiconductor memory device proceeds, the control gate 16 and the floating gate 14 too are being miniaturized. Assuming an inter-electrode permittivity to be ε, an inter-electrode opposing area to be S, and an inter-electrode distance to be L, then a capacitance C is expressed by C=ε(S/L). Therefore, when an opposing area S of the control gate 16 and the floating gate 14 decreases, a capacitance C1 between the control gate 16 and the floating gate 14 in the selected memory cell MC₀ decreases. Now, an amount of charge concentrated in an upper surface of the floating gate 14 by the voltage application to the control gate 16 can be expressed by a product of the capacitance C1 and the potential difference between the control gate 16 and the floating gate 14. Therefore, when the capacitance C1 decreases, the need arises to apply a larger voltage as the write voltage V_{pgm}.

On the other hand, as miniaturization of the nonvolatile semiconductor memory device proceeds, a distance between fellow memory cells MC is becoming closer, and a capacitance C2 between the control gate 16 in the selected memory cell MC₀_{_{—}}N and the floating gates 14 of adjacent memory cells MC₀_{_{—}}N−1 and MC₀_{_{—}}N+1 adjacent to this memory cell MC₀_{_{—}}N is relatively increasing. Therefore, if a larger voltage is applied as the write voltage V_{pgm}, there is a possibility that a miswrite to the adjacent memory cells MC₀_{_{—}}N−1 and MC₀_{_{—}}N+1 occurs. Furthermore, capacitance between fellow floating gates 14 in the selected memory cell MC₀_{_{—}}N and the adjacent memory cells MC₀_{_{—}}N−1 and MC₀_{_{—}}N+1 is also increasing, and this too is one of causes of miswrite increase.

To solve such problems the nonvolatile semiconductor memory device according to the comparative example provides the gap 19₀ between the memory cells MC. That is, since the permittivity ε can be decreased in the gap 19₀, it is possible to decrease the capacitance C2 between the control gate 16 in the selected memory cell MC₀_{_{—}}N and the floating gates 14 of the adjacent memory cells MC₀_{_{—}}N−1 and MC₀_{_{—}}N+1 adjacent to this memory cell MC₀_{_{—}}N. Similarly, it is also possible to decrease the capacitance between fellow floating gates 14 in the selected memory cell MC₀_{_{—}}N and the adjacent memory cells MC₀_{_{—}}N−1 and MC₀_{_{—}}N+1 adjacent to this memory cell MC₀_{_{—}}N. For example, since the permittivity of air is 1.0 and the permittivity of SiO₂ is 3.9, it is conceivable that by adoption of an air gap 19₀, the capacitance C2 between the floating gate 14 and the control gate 16 of adjacent fellow memory cells MC can be reduced to a maximum of about ¼. Therefore, the possibility of a miswrite occurring can be reduced, even in the case where a comparatively large voltage is applied as the write voltage V_{pgm}.

However, the nonvolatile semiconductor memory device according to the comparative example necessitates an even larger write voltage V_{pgm} compared to a structure not including the gap 19₀. This is because in a structure not including the gap 19₀, the capacitance C2 between the floating gate 14 of the selected memory cell MC₀_{_{—}}N and the control gates 16 of the adjacent memory cells MC₀N−1 and MC₀N+1 has a certain magnitude, and it was possible for capacitive coupling with these control gates 16 to be additionally utilized during a write operation. When the write voltage V_{pgm} increases, there is a risk that deterioration of an inter-gate insulating film occurs.

[Write Method in Nonvolatile Semiconductor Memory Device According to First Embodiment]

Next, a write method in the nonvolatile semiconductor memory device according to the present embodiment will be described. FIG. 5 is a schematic view for explaining the write method in the nonvolatile semiconductor memory device according to the present embodiment. The nonvolatile semiconductor memory device according to the present embodiment includes the upper control gate 18 in addition to the lower control gate 16. Therefore, by applying the write voltage V_{pgm} (first write voltage) also to the upper control gates 18 of the adjacent memory cells MC_N−1 and MC_N+1 (referred to below as “adjacent upper control gates”) as well as to the lower control gate 16 of the selected memory cell MC_N (referred to below as “selected lower control gate”) during the write operation, it is possible to perform the write operation by a lower write voltage V_{pgm}. Note that in the present embodiment, the adjacent upper control gate 18 and the selected lower control gate 16 both have the write voltage V_{pgm} applied thereto, but it is also possible for different voltages to be applied to these gates.

Note that in the present embodiment, in order to avoid occurrence of a miswrite to the floating gates 14 of the adjacent memory cells MC_N−1 and MC_N+1 (referred to below as “adjacent floating gates”) due to the upper control gate 18 of the selected memory cell MC_N (referred to below as “selected upper control gate”), a pass voltage Vₚₐₛₛ (first pass voltage) which is lower than the write voltage V_{pgm} is applied to the selected upper control gate 18. However, in a situation where a miswrite to the adjacent memory cells MC_N−1 and MC_N+1 does not occur, it is also possible to apply the write voltage V_{pgm} to the selected upper control gate 18.

In the present embodiment, a pass voltage Vₚₐₛₛ (second pass voltage) is applied to the upper control gate 18 of those of the memory cells MC included in the NAND string to which the selected memory cell MC_N belongs besides the selected memory cell MC_N and the adjacent memory cells MC_N−1 and MC_N+1, that is, to the upper control gate 18 of the memory cells MC_{—}0 to MC_N−2 and MC_N+2 to MC_M−1. This makes it possible to reduce not only the write voltage V_{pgm} but also the pass voltage Vₚₐₛₛ thereby achieving a longer operating life of the insulating layer. Note that in the present embodiment, the selected upper control gate 18 and the upper control gates 18 of the memory cells MC_{—}0 to MC_N−2 and MC_N+2 to MC_M−1 both have the pass voltage Vₚₐₛₛ applied thereto, but it is also possible for different voltages to be applied to these gates.

Furthermore, in the present embodiment, existing voltages (the write voltage V_{pgm} and the pass voltage Vₚₐₛₛ) are applied to the lower control gate 16 and the upper control gate 18. Therefore, there is no need for a power supply circuit to be newly provided to the voltage generating circuit 10, whereby the present embodiment can be easily achieved. However, it is also possible for a new power supply circuit to be provided, and it is also possible for an existing other power supply circuit to be used.

Moreover, in the nonvolatile semiconductor memory device according to the present embodiment, the upper end of the gap 19 is positioned at the lower end of the lower control gate 16. Therefore, firstly, it is possible to reduce the capacitance C2 between the floating gate 14 of the selected memory cell MC_N (referred to below as “selected floating gate”) and the lower control gates 16 of the adjacent memory cells MC_N−1 and MC_N+1 (referred to below as “adjacent lower control gates”) and prevent a miswrite to the adjacent floating gates 14 due to the voltage application to the selected lower control gate 16. Secondly, since the capacitance between the selected floating gate 14 and the adjacent floating gates 14 is also reduced, miswrites are further reduced. Thirdly, it is possible to secure a capacitance C3 between the selected floating gate 14 and the adjacent upper control gates 18 and lower the write voltage V_{pgm}. Note that in order to reduce the capacitance C2, it is considered that the upper end of the gap 19 is formed to be positioned above a center of the first gate insulating layer 15. Moreover, in order to secure the capacitance C3, it is considered that the upper end of the gap 19 is formed to be positioned lower than a center of the lower control gate 16.

Note that the adjacent upper control gates 18 and the adjacent lower control gates 16 are stacked, hence even if the write voltage V_{pgm} is applied to the adjacent upper control gates 18, shielding by the adjacent lower control gates 16 is possible and a miswrite is not caused in the adjacent floating gates 14. Furthermore, although it is conceivable that a miswrite occurs in the memory cells MC_N−2 and MC_N+2 further adjacent to the adjacent memory cells MC_N−1 and MC_N+1, C3 is smaller compared to C1, hence the possibility of this occurring is thought to be low.

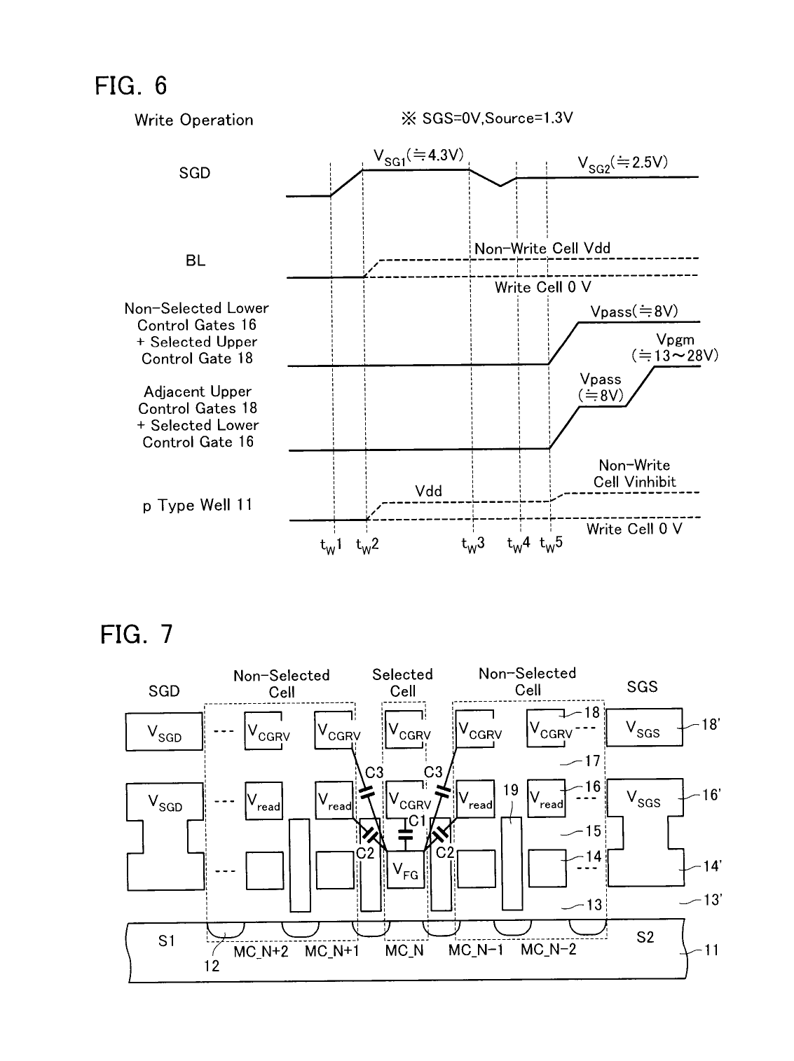

Next, the write method in the present embodiment will be described in more detail. FIG. 6 is a timing chart for explaining same write method. Ata timing when same write method is started, voltages of the select gate lines SGD and SGS, the bit line BL, the lower control gate 16, the upper control gate 18, and the p type well 11 are all set to 0 V (ground potential). In addition, a voltage of the common source line CELSRC is set to, for example, about 1.3 V. At timing t_{w}1, the voltage of the gate electrode SGD is raised to a gate voltage V_{SG1} (≈4.3 V). As a result, the p type well 11 and the bit line BL are electrically connected. At timing t_{w}2, the voltage of the bit line BL connected to the memory cell MC which is a target of the write operation is fixed unchanged at 0 V. Therefore, the voltage of the p type well 11 connected to here is also fixed unchanged at 0 V. Additionally, at same timing t_{w}2, the voltage of the bit line BL connected to the non-write memory cell MC which is not the target of the write operation is raised to a voltage Vdd. Therefore, the potential of the p type well 11 connected to the non-write memory cell MC is raised to Vdd.

At timing t_{w}3, the voltage of the select gate line SGD is lowered, and at timing t_{w}4, the voltage of the select gate line SGD is again raised to a gate voltage V_{SG2} (≈2.5 V). As a result, the p type well 11 connected to the non-write memory cell MC attains a higher potential than the gate of the select gate transistor S1, and said p type well 11 is electrically disconnected from the bit line BL and attains a floating state. At timing t_{w}5, the voltage of each of the lower control gates 16 and the upper control gates 18 is raised to the pass voltage Vₚₐₛₛ (≈8 V) to form a channel from the select gate transistor S1 to the selected memory cell MC. Following this, the voltage of the selected lower control gate 16 and the adjacent upper control gates 18 is further raised to the write voltage V_{pgm} (≈13 to 28 V). Note that a value of the write voltage V_{pgm} differs according to a target threshold level. As a result, in the write-target memory cell MC, a voltage is applied between the floating gate 14 and the p type well 11, whereby a charge is accumulated in the floating gate 14 by a tunnel current. On the other hand, in the memory cell MC which is not the write target, the p type well 11 is in a floating state, hence simultaneously to application of the write voltage V_{pgm}, the potential of the p type well 11 is raised to an inhibit potential V_{inhibit}, whereby a charge is not accumulated.

After the write operation shown in FIG. 6, a verify operation is performed, and when a threshold of the write cell does not achieve a certain value, the write operation is re-performed. At this time, the voltage of the write voltage V_{pgm} of the selected lower control gate 16 and the adjacent upper control gates 18 is stepped up by, for example, about 0.5 to 1 V. Then, the write operation and the verify operation are repeatedly performed until the threshold of the write cell attains the certain value. A width of increase of the write voltage V_{pgm} at this time is preferably set to the same width in the selected lower control gate 16 and the adjacent upper control gates 18.

[Read Method in Nonvolatile Semiconductor Memory Device According to First Embodiment]

Next, a read method in same embodiment will be described. FIG. 7 is a schematic view for explaining the read method in the nonvolatile semiconductor memory device according to the present embodiment. In same read operation, when performing the read operation, a select read voltage V_{CGRV} is applied to each of the upper control gates 18 and the selected lower control gate 16, and a non-select read voltage V_{read} (second read voltage) which is larger than the select read voltage V_{CGRV} is applied to the lower control gates 16 of non-selected memory cells MC_{—}0 to MC_N−1 and MC_N+1 to MC_M−1 (referred to below as “non-selected lower control gates”). Note that in the present embodiment, the non-select read voltage V_{read} is applied uniformly to the non-selected lower control gates 16, but it is also possible for, for example, a different voltage to be applied to the adjacent lower control gates 16 and the lower control gates 16 of the non-selected memory cells MC_{—}0 to MC_N−2 and MC_N+2 to MC_M−1, that is the non-selected memory cells besides the adjacent memory cells MC_N−1 and MC_N+1.

When the memory cell MC is capable of storing n-level portions of data, n−1 types of the select read voltage V_{CGRV} are set. Moreover, the memory cell MC stores its threshold voltage as data by accumulating a charge in the floating gate 14, and the select read voltages V_{CGRV} are set between fellow threshold voltages expressing different data. Therefore, by applying the select read voltage V_{CGRV} to the selected lower control gate 16 and confirming whether a current flows between the source and drain of the selected memory cell MC_N or not, it is possible to determine data held in the selected memory cell MC_N. Furthermore, in order to confirm a conductive state of the selected memory cell MC_N, it is required to set the non-selected memory cells to an ON state regardless of data held in the non-selected memory cells, and the non-select read voltage V_{read} is a voltage for this. Therefore, the non-select read voltage V_{read} is set larger than the largest threshold of the memory cell MC and the maximum value of the select read voltage V_{CGRV}.

In the present embodiment, during the read operation, the select read voltage V_{CGRV} is applied not only to the selected lower control gate 16 but also to each of the upper control gates 18. Therefore, in the read operation too, the capacitance C3 can be utilized to reduce the select read voltage V_{CGRV} and the non-select read voltage V_{read} to achieve a longer operating life of the insulating layer. Note that in the present embodiment, the identical voltage (the select read voltage V_{CGRV}) is applied to both of the upper control gates 18 and the selected lower control gate 16, but it is also possible for different voltages to be applied. Furthermore, in the present embodiment, the identical voltage (the select read voltage V_{CGRV}) is applied to both of the upper control gates 18 of the non-selected memory cells MC_{—}0 to MC_N−1 and MC_N+1 to MC_M−1 and the selected upper control gate 18, but it is also possible for different voltages to be applied.

Furthermore, since the upper end of the gap 19 is positioned at the lower end of the lower control gate 16, it is possible to decrease the capacitance C2 of fellow floating gates 14 to achieve an improvement in read accuracy, and it is possible to secure the capacitance C3 between the selected floating gate 14 and the adjacent upper control gates 18 to reduce the non-select read voltage V_{read}.

Note that in the read operation according to the present embodiment, the select read voltage V_{CGRV} is applied to the selected upper control gate 18. This is because the non-select read voltage V_{read} is larger than the select read voltage V_{CGRV} and there is a risk that if the non-select read voltage V_{read} is applied to the selected upper control gate 18, then the selected memory cell MC ends up attaining an ON state regardless of an amount of charge accumulated in the selected floating gate 14. Therefore, if read is performed appropriately in view of a magnitude of the non-select read voltage V_{read} or a distance between the selected floating gate 14 and the adjacent upper control gates 18, and so on, then it is also possible for the non-select read voltage V_{read} to be applied to the selected upper control gate 18. Moreover, it is also possible for the select read voltage V_{CGRV} to be applied to the adjacent upper control gates 18 and the upper control gates 18 of the memory cells MC_N−2 and MC_N+2 further adjacent to the adjacent memory cells MC_N−1 and MC_N+1, and for the non-select read voltage V_{read} to be applied to the other upper control gates.

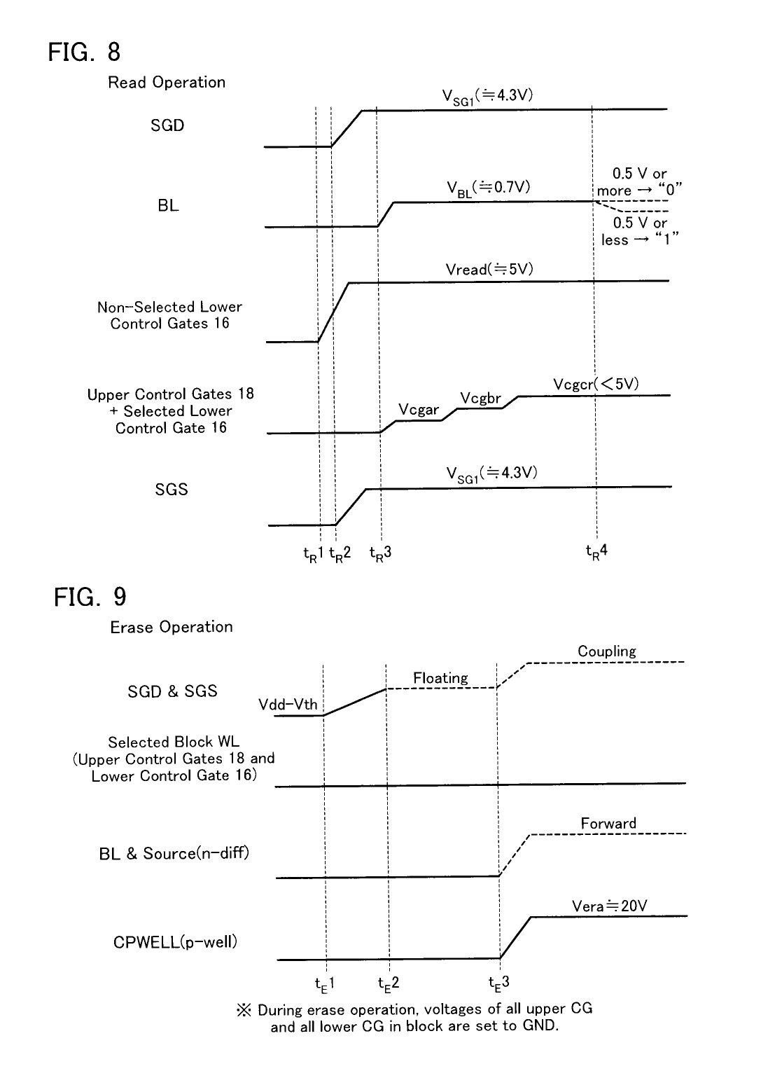

Next, the read method according to the present embodiment will be described in more detail. FIG. 8 is a timing chart for explaining same read method. At a timing when same read method is started, voltages of the select gate lines SGD and SGS, the bit line BL, the lower control gate 16, and the upper control gate 18 are all set to 0 V (ground potential). At timing t_{R}1, the voltage of the non-selected lower control gates 16 is raised to the non-select read voltage V_{read} (≈5 V). As a result, a channel is formed directly below the non-selected memory cells MC. At timing t_{R}2, the potential of the select gate lines SGD and SGS is raised to the gate voltage V_{SG1} (≈4.3 V), whereby the channel formed on a select gate transistor S1 side is connected to the bit line BL and the channel formed on a select gate transistor S2 side is connected to the common source line CELSRC. At timing t_{R}3, the voltage of the bit line BL is raised to a bit line voltage V_{BL} (≈0.7 V). As a result, a bias voltage is applied between the source and drain of the selected memory cell MC_N. Additionally, at same timing t_{R}3, the voltage of the upper control gates 18 and the voltage of the selected lower control gate 16 is sequentially increased to read voltages corresponding to each of read levels. As a result, the selected memory cell MC_N attains an ON state at a timing based on a threshold, whereby a current flowing in the bit line BL changes. Therefore, by detecting by the sense amplifier 2a timing t_{R}4 at which the current flowing in the bit line BL has changed, it is possible to determine data being held by the memory cell MC.

[Erase Method of Nonvolatile Semiconductor Memory Device According to First Embodiment]

Next, an erase method of the nonvolatile semiconductor memory device according to the first embodiment of the present invention will be described. FIG. 9 is a timing chart for explaining same erase method. At timing t_{E}1, the potential of the select gate lines SGD and SGS is gradually raised and at timing t_{E}2, the select gate lines SGD and SGS are set to a floating state. In addition, at timing t_{E}3, an erase voltage Vₑᵣₐ (≈20 V) is applied to the p type well 11. Moreover, the voltage of the word line WL (lower control gate 16 and upper control gate 18) is fixed at a ground potential. As a result, a voltage is applied to the tunnel insulating layer 13, and a charge accumulated in the floating gate 14 flows into the p type well 11 by a tunnel current.

The present embodiment includes the upper control gate 18 as well as the lower control gate 16, hence during the erase operation too, it becomes possible to additionally use capacitive coupling between the floating gate 14 and the upper control gate 18 to perform erase more reliably.

[Nonvolatile Semiconductor Memory Device According to Second Embodiment]

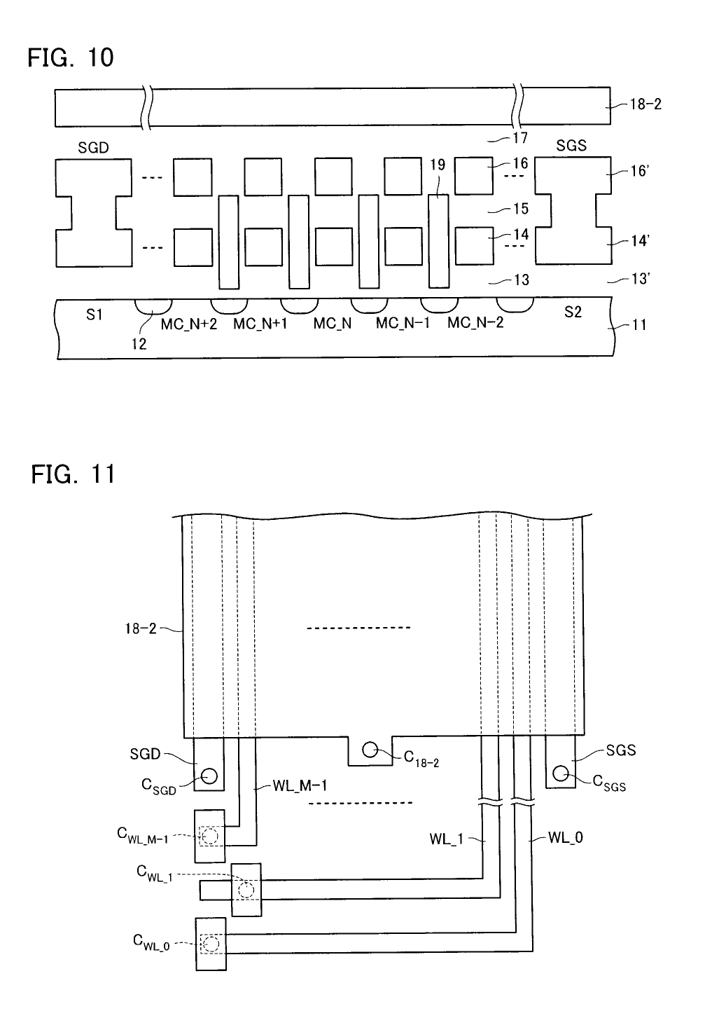

Next, a nonvolatile semiconductor memory device according to a second embodiment of the present invention will be described. FIG. 10 is a schematic cross-sectional view for explaining a configuration of the nonvolatile semiconductor memory device according to the present embodiment. The nonvolatile semiconductor memory device according to the present embodiment is basically configured similarly to the nonvolatile semiconductor memory device according to the first embodiment. However, whereas in the nonvolatile semiconductor memory device according to the first embodiment, the upper control gate 18 was divided in the row direction on a memory cell MC basis, in the present embodiment, an upper control gate 18-2 is formed in a plate-like shape extending in a plane configured from the direction of extension of the p type well 11 and the direction of extension of the word line WL (this plane could also be said to be “a plane parallel to a substrate surface”). Moreover, said upper control gate 18-2 covers an upper portion of all memory cells MC and the select gate transistors S1 and S2 present in an identical block BLK.

In the nonvolatile semiconductor memory device according to the first embodiment, the upper control gate 18 was divided in the row direction on a memory cell MC basis, hence in a manufacturing process it is considered necessary to manufacture a stacked body of the upper control gate 18, the second inter-gate insulating layer 17, the lower control gate 16, the first inter-gate insulating layer 15, and the floating gate 14. Such a configuration has a large aspect ratio and there is a risk of buckling and so on occurring during manufacturing. However, in the nonvolatile semiconductor memory device according to the present embodiment, the upper control gate 18-2 is configured in a plate-like shape extending on a plane. It is therefore considered possible for the device to be manufactured without the need for an advanced manufacturing process.

Note that in the present embodiment, the upper control gate 18-2 is configured in a plate-like shape covering directly above all memory cells MC present in an identical block BLK. However, this is not necessarily required, and the upper control gate 18-2 may be configured to cover two or more of the lower control gates 16. Moreover, depending on a situation, it is also possible for the upper control gate 18-2 to be divided in a different direction to the lower control gate 16.

FIG. 11 is a schematic plane view showing a configuration of the nonvolatile semiconductor memory device according to the present embodiment. In the nonvolatile semiconductor memory device according to the present embodiment, the word line WL (corresponding to lower word line LWL in the first embodiment) led out from each block BLK is connected to the row control circuit 3 by a respective word line contact C_{WL}. In addition, the upper control gate 18-2 comprises an upper control gate contact C₁₈₋₂ outside each block BLK so as to avoid the bit line BL (not illustrated), and is connected to the row control circuit 3 by this upper control gate contact C₁₈₋₂.

That is, in the first embodiment, a plurality of lower control gates 16 and upper control gates 18 were present and it was required that these each be provided with a contact and connected to the row control circuit, hence there was a risk of this leading to complication of the manufacturing process. In contrast, in the present embodiment, there exists only one upper control gate per one block BLK, hence complication of the manufacturing process can be prevented. Note that even when the upper control gate 18-2 is divided into a plurality, the contact is considered capable of being manufactured more easily compared to in the first embodiment.

[Operation of Nonvolatile Semiconductor Memory Device According to Second Embodiment]

Next, operations of the nonvolatile semiconductor memory device according to the present embodiment will be described. Note that an erase operation can be performed similarly to in the first embodiment, hence a description thereof will be omitted.

[Write Method in Nonvolatile Semiconductor Memory Device According to Second Embodiment]

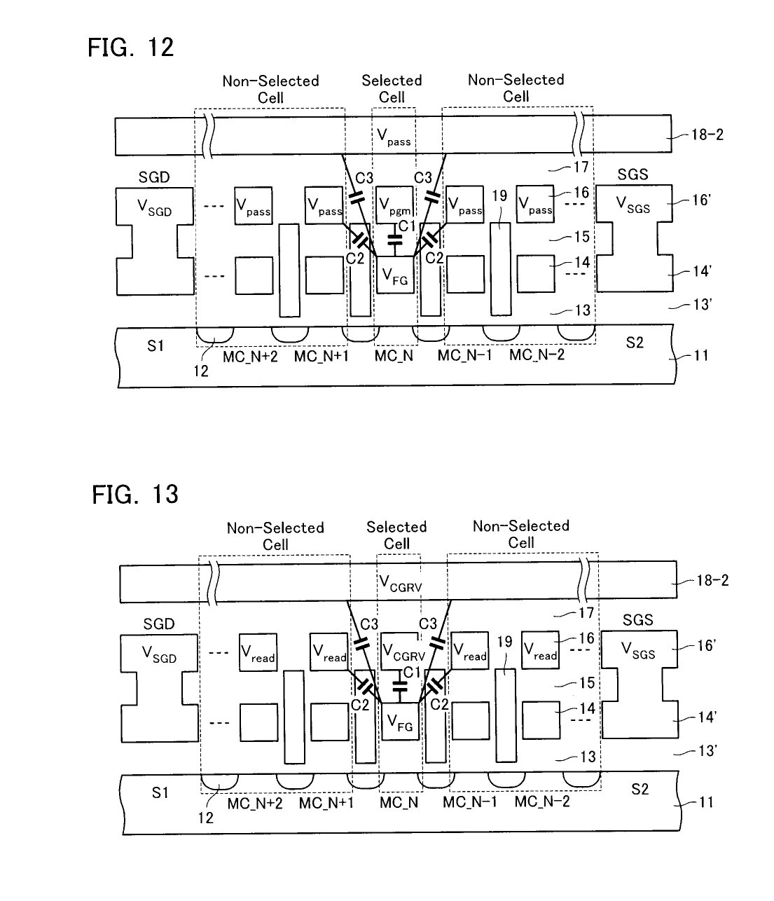

Next, a write method in the nonvolatile semiconductor memory device according to the present embodiment will be described. FIG. 12 is a schematic view for explaining the write method in the nonvolatile semiconductor memory device according to the present embodiment. The nonvolatile semiconductor memory device according to the present embodiment includes the plate-like upper control gate 18-2. Therefore, the capacitance C3 between the selected floating gate 14 and the upper control gate 18-2 becomes larger compared to in the first embodiment. Therefore, a voltage state of the upper control gate 18-2 more greatly affects the floating gate 14 compared to in the first embodiment. On the other hand, in the present embodiment, the upper control gate 18-2 is configured in a plate-like shape, hence there is a risk that when the write voltage V_{pgm} is applied here, a miswrite occurs in the non-selected memory cell MC. Therefore, in the present embodiment, the pass voltage Vₚₐₛₛ is applied to the upper control gate 18-2. The voltages applied to the lower control gate 16 or the select gate lines SGS and SGD and so on are similar to those in the first embodiment. As a result, in the present embodiment too, it is possible to reduce the write voltage Vpgm and achieve a longer operating life of the insulating layer.

[Read Method in Nonvolatile Semiconductor Memory Device According to Second Embodiment]

Next, a read method of the nonvolatile semiconductor memory device according to the present embodiment will be described. FIG. 13 is a schematic view for explaining the read method in the nonvolatile semiconductor memory device according to the present embodiment. Said read method is basically similar to that in the first embodiment. However, in the nonvolatile semiconductor memory device according to the present embodiment, the upper control gate 18-2 is formed in a plate-like shape, hence the select read voltage V_{CGRV} is applied to said upper control gate 18-2. As mentioned above, in the present embodiment, the capacitance between the floating gate 14 and the upper control gate 18-2 becomes larger compared to in the first embodiment. Therefore, it is considered possible for the select read voltage V_{CGRV} and the non-select read voltage V_{read} to be even more greatly reduced compared to in the first embodiment.

[Other]

In the embodiments described above, when two voltage values are said to be substantially identical, they have a voltage difference of 1 V or less, and when two voltage values are said to be identical, they have a voltage difference of 0.5 V or less.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device, comprising:
a memory cell array which has a plurality of memory cells arranged in a first direction to share a source and a drain with each other; and
a control circuit,
the memory cell including:
a semiconductor layer;
a gate insulating layer formed on the semiconductor layer;
a floating gate formed on the gate insulating layer;
a first inter-gate insulating layer formed on the floating gate;
a lower control gate formed on the first inter-gate insulating layer;
a second inter-gate insulating layer formed on the lower control gate; and
an upper control gate formed on the second inter-gate insulating layer, and
the control circuit,
when performing a write operation on a certain selected memory cell,
applying a first pass voltage to the upper control gate in the selected memory cell, and
applying a first write voltage which is larger than the first pass voltage to the upper control gate in an adjacent memory cell adjacent to the selected memory cell in the first direction.

2. The nonvolatile semiconductor memory device according to claim 1, wherein
the plurality of memory cells arranged in the first direction form a NAND string, and
the control circuit, when performing the write operation on the selected memory cell,
applies a second pass voltage which is smaller than the first write voltage to the upper control gate in those of the memory cells included in the NAND string to which the selected memory cell belongs other than the selected memory cell and the adjacent memory cell.

3. The nonvolatile semiconductor memory device according to claim 1, wherein
the control circuit, when performing the write operation on the selected memory cell,
applies a second write voltage of a magnitude substantially identical to that of the first write voltage to the lower control gate in the selected memory cell.

4. The nonvolatile semiconductor memory device according to claim 1, wherein
the control circuit, when performing the write operation on the selected memory cell,
applies the first write voltage to the upper control gate in the adjacent memory cell and performs a verify operation, and then increases a magnitude of the first write voltage to re-perform the write operation.

5. The nonvolatile semiconductor memory device according to claim 1, wherein
the control circuit, when performing the write operation on the selected memory cell,
applies a voltage to the upper control gate and the lower control gate at a substantially identical timing.

6. The nonvolatile semiconductor memory device according to claim 1, wherein
the memory cell array has formed therein a gap adjacent to the memory cell from the first direction, and
an upper end of the gap is positioned lower than a lower end of the lower control gate.

7. A nonvolatile semiconductor memory device, comprising:
a memory cell array which has a plurality of memory cells arranged in a first direction to share a source and a drain with each other; and
a control circuit,
the memory cell including:
a semiconductor layer;
a gate insulating layer formed on the semiconductor layer;
a floating gate formed on the gate insulating layer;
a first inter-gate insulating layer formed on the floating gate;
a lower control gate formed on the first inter-gate insulating layer;
a second inter-gate insulating layer formed on the lower control gate; and
an upper control gate formed on the second inter-gate insulating layer, and
the control circuit,
when performing a read operation on a certain selected memory cell,
applying a first read voltage to the upper control gate in an adjacent memory cell adjacent to the selected memory cell in the first direction, and
applying a second read voltage which is larger than the first read voltage to the lower control gate in the adjacent memory cell.

8. The nonvolatile semiconductor memory device according to claim 7, wherein
the control circuit, when performing the read operation on the selected memory cell,
applies a third read voltage which is smaller than the second read voltage to the lower control gate in the selected memory cell.

9. The nonvolatile semiconductor memory device according to claim 7, wherein
the control circuit, when performing the read operation on the selected memory cell,
applies a third read voltage which is substantially equal to the first read voltage to the lower control gate in the selected memory cell.

10. The nonvolatile semiconductor memory device according to claim 7, wherein
the control circuit, when performing the read operation on the selected memory cell,
applies a fourth read voltage which is substantially equal to the first read voltage to the upper control gate in the selected memory cell.

11. The nonvolatile semiconductor memory device according to claim 7, wherein
the control circuit, when performing the read operation on the selected memory cell,
applies a voltage to the upper control gate and the lower control gate in the selected memory cell at a substantially identical timing.

12. The nonvolatile semiconductor memory device according to claim 7, wherein
the memory cell array has formed therein a gap adjacent to the memory cell from the first direction, and
an upper end of the gap is positioned lower than a lower end of the lower control gate.

13. A nonvolatile semiconductor memory device, comprising:
a memory cell array which has a plurality of memory cells arranged in a first direction to share a source and a drain with each other; and
a control circuit that applies a voltage to the memory cell array,
the memory cell including:
a semiconductor layer;
a gate insulating layer formed on the semiconductor layer;
a floating gate formed on the gate insulating layer;
a first inter-gate insulating layer formed on the floating gate;
a lower control gate formed on the first inter-gate insulating layer;
a second inter-gate insulating layer formed on the lower control gate; and
an upper control gate formed on the second inter-gate insulating layer, and
the upper control gate being formed in a planar shape extending in a plane substantially perpendicular to a stacking direction of the memory cell, and the control gate being shared by the plurality of memory cells.

14. The nonvolatile semiconductor memory device according to claim 13, further comprising:
a select gate transistor,
wherein the plurality of memory cells arranged in the first direction, along with the select gate transistor, forma NAND string having one end connected to a bit line and the other end connected to a source line,
the select gate transistor includes:
the semiconductor layer;
a select gate insulating layer formed on the semiconductor layer; and
agate electrode formed on the select gate insulating layer, and
an upper portion of the select gate transistor is opposed by the upper control gate via an insulating layer.

15. The nonvolatile semiconductor memory device according to claim 13, wherein
the memory cell array has formed therein a gap adjacent to the memory cell from the first direction, and
an upper end of the gap is positioned lower than a lower end of the lower control gate.

16. The nonvolatile semiconductor memory device according to claim 13, wherein
the control circuit, when performing a write operation on a certain selected memory cell,
applies a first pass voltage to the upper control gate, and
applies a first write voltage which is larger than the first pass voltage to the lower control gate in the selected memory cell.

17. The nonvolatile semiconductor memory device according to claim 16, wherein
the control circuit, when performing the write operation on the selected memory cell,
applies a voltage to the upper control gate and the lower control gate at a substantially identical timing.

18. The nonvolatile semiconductor memory device according to claim 13, wherein
the control circuit, when performing a read operation on a certain selected memory cell,
applies a first read voltage to the upper control gate, and
applies a second read voltage which is larger than the first read voltage to the lower control gate in an adjacent memory cell adjacent to the selected memory cell in the first direction.

19. The nonvolatile semiconductor memory device according to claim 18, wherein
the control circuit, when performing the read operation on the selected memory cell,
applies a third read voltage which is smaller than the second read voltage to the lower control gate in the selected memory cell.

20. The nonvolatile semiconductor memory device according to claim 18, wherein
the control circuit, when performing the read operation on the selected memory cell,
applies a voltage to the upper control gate and the lower control gate at a substantially identical timing.
